(19) United States
(12) Patent Application Publication
(10) Pub. No.: US 2010/0284213 A1
(43) Pub. Date: Nov. 11, 2010

(54) Method of cross-point memory programming and related devices

(76) Inventor: Semyon D. Savransky, Newark, CA (US)

Correspondence Address: Daniel R. Shepard;Contour Semiconductor, Inc., Bldg. 5, 101 Billerica Ave., No. Billerica, MA, 01862, US

(21) Appl. No.: 12/800,006

(22) Filed: May 6, 2010

Related U.S. Application Data
(60) Provisional application No. 61/215,473, filed on May 6, 2009.

(51) Int. Cl. G11C 11/00

(52) U.S. Cl. 365/163; 365/175; 365/148

(57) ABSTRACT

A reverse recovery current of a diode is used for programming a cross-point memory. Programming of a crossbar memory device, comprising a diode with preferably short charge carriers lifetime and a storage element by keeping the device at one polarity for a period of time and then switching it from first polarity to second polarity (e.g., forward to reverse polarity of the diode). Programming occurs due to diode's reverse recovery current. The value and duration of the recovery current pulse are selected to program the storage element into one of plurality of electrically distinguish states by variation of the level of current flowing through the device in the first polarity of applied bias voltage, by variation of the speed for changing the bias voltage from first polarity to second polarity, and by steady state value of the second polarity voltage applied to the device in one or more embodiments.

### CROSS REFERENCE TO RELATED APPLICATIONS

This application claims priority to and the benefit of, and incorporates herein by reference in its entirety, U.S. Provisional Patent Application No. 61/215,473 which was filed on May 6, 2010.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

The present invention relates to semiconductor memory devices, and more particularly, to a cross-point memory programming.

A variety of computer memory technologies are used to store computer programs and data. Examples of the computer memory technologies include a dynamic random access memory (DRAM), a static random access memory (SRAM), an erasable programmable read-only memory (EPROM), and an electrically erasable programmable read-only memory (EEPROM). Some memory technologies need a voltage to retain stored data, while other memory technologies do not need a voltage to retain stored data.

There is an increasing demand for a nonvolatile memory that can be repetitively read and written. A typical example of the nonvolatile memory is a flash memory. The flash memory uses a floating gate transistor that retains charges on an insulated floating gate. Each memory device of the flash memory can be electrically programmed to “1” or “0” by injecting/removing electrons into/from the floating gate. However, it is difficult to further scale down memory devices. Further, memory devices consume a relatively large amount of power, and their read/program speed is relatively slow.

A recent alternative to flash memory is two-terminal memory devices based on materials which electrical properties are changed under influence of external signals. A generic two terminal storage element 100 consists of an active material 110 between two electrically conductive electrodes 120A and 120B as shown in FIG. 1A.

Phase change memory (PCM) devices are the most promising nonvolatile two terminal storage elements for 45 nm and smaller size non-volatile memory. PCM use a phase change alloy (PCA) 110 that can be electrically changed between different structured states having different electrical read characteristics. PCA is programmed between an amorphous state with a relatively high resistivity and a crystalline state with a relatively low resistivity. PCA material is programmed by heating from electrical pulses in PCM. The pulses polarities (positive or negative) are not important for PCM. The heating intensity and heating time duration determine whether the PCA is in an amorphous or crystalline state. High and low resistances represent programmed values “1” and “0”, which can be sensed by measuring the resistivity of the active material 110.

In a typical cross-point memory, a crossbar memory device includes a storage element and a selector element. The selector element is a diode for most cost-effective cross-point memories. The two terminal storage element is essentially variable resistor or variable capacitor or variable switch. As illustrated in FIG. 1B, the simplest crossbar memory device 140 consist of a lower electrode 120A, the diode 130 electrically connected with an active material 110, and an upper electrode 120B. An electrical current flows between the electrodes 120A and 120B through the diode 130 and the active material 110 when an electrical pulse is applied to the memory device.

The active material 110 can be a PCA such as germanium-antimony-tellurium or indium-antimony-tellurium. The diode 130 can be p-n, or p-i-n, or Schottky, or Zener diode.

For the sake of simplicity, only PCM is described as a storage element, although it should be appreciated that the embodiments of the invention can be implemented for programming of any storage element which state can be changed by an electrical pulse.

When a pulse current with a very short pulse of several ns to several tens of ns is applied to the memory device, only a portion of the PCA is heated by Joule heat. At this point, a heating profile difference changes the PCA portion into a crystalline state (or a “set state”) or an amorphous state (or a “reset state”). For example, as illustrated in FIG. 2, a first pulse current Irst is applied to the PCM and is removed within a short time of about 10 ns in order to change the PCA 110 into an amorphous state (or a reset state). Also, as illustrated in FIG. 2, a second pulse current Iset smaller than the first pulse current it is applied to the memory device and is removed after a time period of about 300 ns in order to change the PCA 3 into a crystalline state (or a set state). Thus, the PCM device is set to one of the crystalline state and the amorphous state according to the above-described method. A crossbar memory device can be programmed into more than one reset state and/or more than one set state in case of multi-level cell (MLC) memory.

The main problems of the cross-point memories are quite high reset current Irst about 1 mA (for 90 nm memory device) that is necessary to heat up a region inside PCA 110 to a temperature above the melting temperature Tm. Quite long set current Iset about 300 uA (for 90 nm device) heats PCA 110 above the glass transition temperature Tg up to the crystallization temperature Tx. For all known PCA Tm>Tx>Tg and it is important to reach Tm or higher temperature during programming of a PCM device into the reset state.

Most of 90 nm diodes 130 can barely supply reset current for 90 nm device (FIG. 3). At 45 nm device node regular a silicon diode 130 can supply current for set operation and it capability for high forward current is not enough to reset PCA 110. The situation becomes even worse with PCM scaling below 45 nm as shown in FIG. 4.

To reduce the programming current, the most straightforward way is to shrink the heating region of PCA. Several documents, e.g., U.S. Pat. No. 7,067,865 disclose PCM devices with reduced heating area of PCA. These devices are based on the formation of the sub-lithographic features on the contact between at least one electrode and PCA. Tight control of such devices in mass production is also difficult. Generally, three or more additional lithographic steps are needed to form such devices. It is desirable to minimize the number of lithographic steps in manufacture of the device.

Further, the programming current reduction can be based on thermal insulation of the heating region. Several publications including U.S. Pat. No. 6,815,704 disclose phase-change memory devices with good thermal insulation of the heating region. These devices are based on the formation of the heating region well inside PCA. Such device cannot be effectively cooled during programming PCM into a reset state, and, as the result, PCA in their reset state is partially crystalline. Therefore such PCM devices have small dynamic range of resistances and limited retention.

Almost all prior art for cross-point phase change memories use forward diode current If to program PCA. The only exclusion are U.S. Pat. Nos. 7,304,888, 7,492,630, and 7499304 that teach to use constant reverse diode current Ir for writing memory devices in a memory array. The authors of these inventions did not consider how to improve current density characteristics of a diode and did not consider pulses of the reverse diode current.

Small current density of a diode limits scalability of a cross-point memory, therefore it is important to find a method of programming storage elements that overcome this limit. Therefore alternatives to a conventional diode or to the forward current programming method are needed.

Several publications including U.S. Pat. Nos. 3,571,809, 6,795,338, and 7382647, as well as USPTO Application No. 20080113464 propose to use volatile chalcogenide threshold switching element or chalcogenide solid electrolyte with high current density capabilities instead of a diode in a memory array. Several publications including the paper “New selector based on zinc oxide grown by low temperature atomic layer deposition for vertically stacked non-volatile memory devices” by N. Huby et. al. published in Microelectronic Engineering, Volume 85, Issue 12, Dec. 2008, Pages 2442-2444 propose to use non-silicon diodes. Although these solutions are valid they required to introduce new materials in CMOS process in addition to the active material 110 that can be very difficult.

### SUMMARY OF THE INVENTION

Broadly speaking, the embodiments of the present invention fill industry needs by providing methods for programming a cross-point memory.

In particular, the present invention fill industry needs a cross-point phase change memory, and for programming a phase change memory into reset state using a diode as the selector device.

Some embodiments of the present invention are based on ability of PCA to be programmed to different states regardless of polarity of electric pulses, and/or existence of high reverse recovery currents in a diode which current density exceed the forward current density in the diode.

According to some embodiments of the invention, the programming a memory device occurs due to the reverse recovery current.

The value and duration of a reverse recovery current are selected to program PCA into set or reset state by variation of factors such as forward voltage, or/and speed of change voltage polarity that define the reverse recovery current in some embodiments of the invention.

According to some embodiments of the invention, the diode has short charge carriers' lifetime.

According to some embodiments of the invention, a memory device or/and a memory array has finite reactance or/and inductance. This inductance can be related with a storage element, or with one or more electrodes of a crossbar memory device, or with bitline(s), or with wordline(s), or with inductive load to the array.

It should be appreciated that the embodiments of the invention can be implemented for programming of any storage element which state can be changed by an electrical pulse.

It should be appreciated that the embodiments of the invention can be implemented in numerous ways, including an apparatus, a system, or a device.

### BRIEF DESCRIPTION OF THE DRAWINGS

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1A shows a generic storage element according a prior art.

FIG. 1B shows a generic crossbar memory device according a prior art.

FIG. 2 shows programming SET and RESET pulses according a prior art.

FIG. 3 shows 90 nm diode I-V characteristics.

FIG. 4 illustrates a reset current and current densities for a typical two terminal storage elements as a function of critical dimension of a memory device.

FIG. 5 shows a generic crossbar memory device according an embodiment of this invention and its electrical schematic.

FIG. 6 shows a reverse recovery current of a diode.

FIG. 7 shows programming pulses for a set and reset states according to some embodiments of the invention.

FIG. 8 shows an apparatus comprising a write circuit, a cross-point memory, and interface devices.

### DETAILED DESCRIPTION

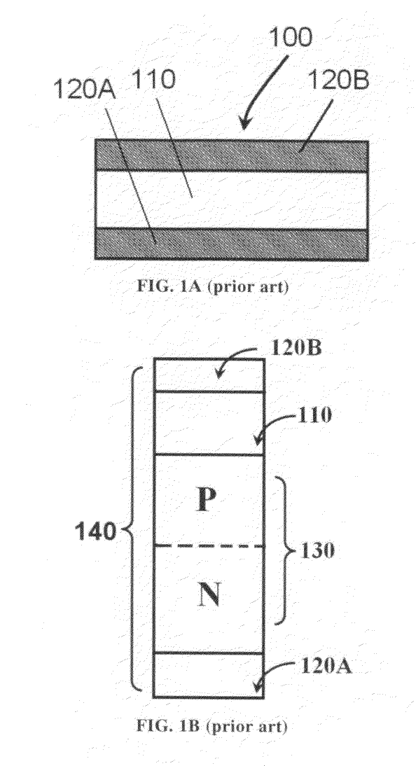

Several exemplary embodiments of the invention will now be described in details with reference to the accompanying drawings shown in FIGS. 1-8.

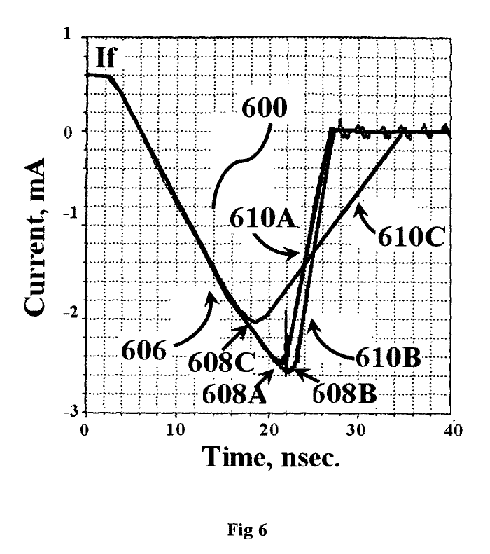

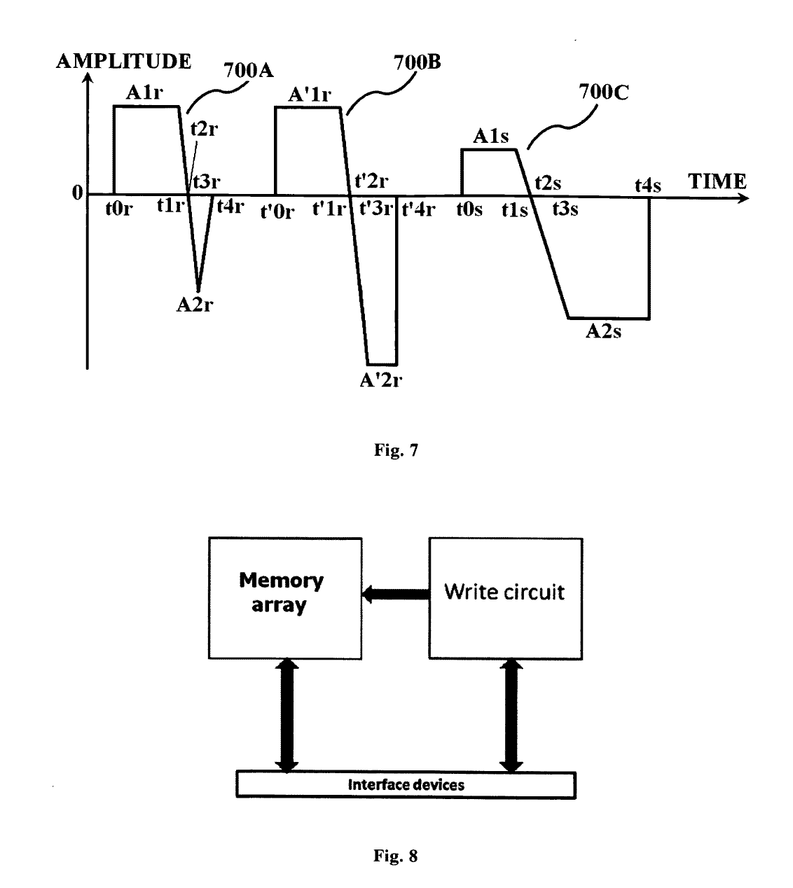

FIGS. 1-4 are explained in the background section of this invention. FIG. 5 shows a crossbar memory device 500 according to some embodiments of this invention and its electrical schematic. FIG. 6 shows examples of reverse recovery current pulses 600. FIG. 7 shows external signal pulses 700 applied to the memory device 500 in order to create various reverse recovery current pulses 600 needed to program the memory device 500 into one of non-volatile states.

A storage element 510 and a diode 530 electrically coupled in a crossbar memory device 500 as shown in FIG. 5. At least one of the storage element 510 or/and the diode 530 has finite (non-zero) reactance.

The storage element 510 is selected from the group consisting of a phase-change memory (PCM, PRAM, PCRAM, PC-RAM), a resistive memory (RRAM), a magnitoresistive memory (MRAM), a polymer memory (PRAM), a molecular memory, a ferroelectric memory (FeRAM), an ionic memory (PMC), a memristive memory, a spin memory, an oxide memory such as ReRAM, 0xRAM, RRAM, a conductive bridging random access memory (CBRAM). The storage element 510 that can be made from be a phase change alloy, e.g. Ge—Sb—Te; or an ion conductor, e.g. Cu—Ge—Se; or a metal-oxide, e.g. TiO2, or a ferroelectric, or a perovskite, or a marnetoresistor, e.g. a colossal magnetoresistive (CMR) film, or a transition metal oxide, or a Mott insulator.

A crossbar memory device 500 in one or more embodiments has a first electrode 520A and a second electrode 520B. The first electrically conductive electrode 520A electrically and mechanically coupled with the diode 530. The second electrically conductive electrode 520B electrically and mechanically coupled with the storage element 510. The electrodes 520A and 520B can be made from any material with good electrical conductivity, e.g., from metal such as W, Ag, Al, Ti or Cu; or from semiconductors such as doped Si; or from carbon C, or from a superconductor, or from ion conductor.

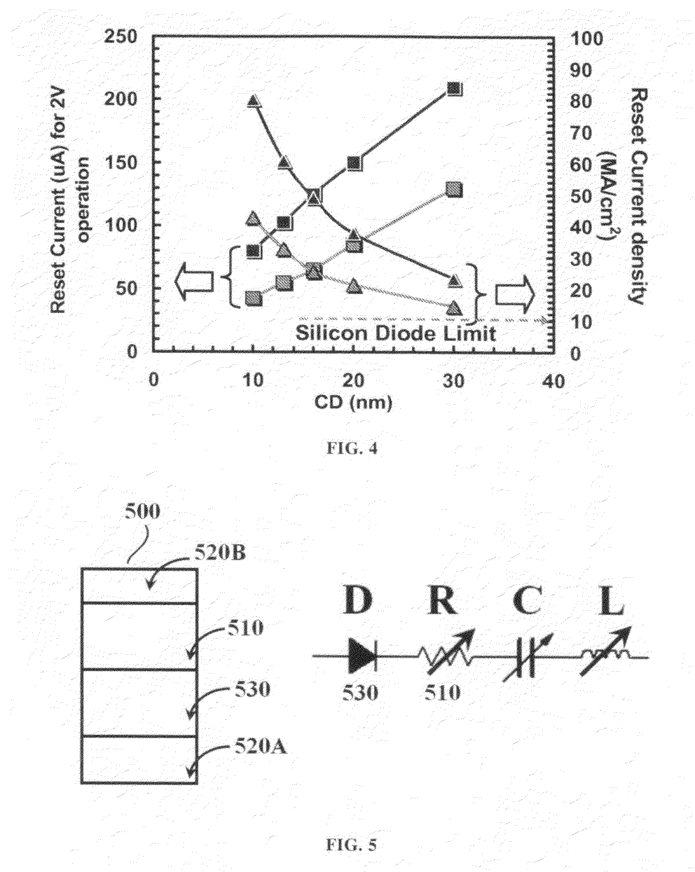

The diode 530 should have short charge carriers' lifetime, smaller than 3 us, preferably smaller than 100 ns. The diode 530 can be made from Si, SiGe, GaAs or another crystalline, polycrystalline or amorphous material with static I-V characteristic similar to one shown in FIG. 3.

According to some embodiments of the invention at least one of the storage element 510 or/and the electrodes 520 has finite inductance; and at least one of the diode 530 under a reverse bias or/and the storage element 510 or/and the electrodes 520 has finite capacitance; as well as at least one of the diode 530 under a reverse bias or/and the storage element 510 has finite resistance as shown in electrical schematic of FIG. 5. Usually a crossbar storage element 510 has variable resistance and capacitance that can be programmed by an external signal, therefore it is suitable for a non-volatile memory. The resistance of the crossbar memory device 500 can be changed in the range from about 10 Ohm to about 100 GOhm, it inductance is less than 1 mH, and it capacitance can be changed in the range from zero to less than about 1 mF. A generic electrical scheme of a crossbar memory device 500 is shown in FIG. 5.

The crossbar device 500 and hence the storage element 510 and the diode 530 critical dimensions scalable to single or decimal nanometers size as shown in FIG. 4.

Low resistance of a diode 530 under a forward bias as shown in FIG. 3 is due to a large concentration of free charge carriers that flow through the diode 530. To switch the bias signal 700 (e.g., bias voltage) from forward to a reverse, it is necessary to remove these free charge carriers to enable the formation of a depletion region in the diode 530. The process of switching of a diode 530 from the forward conductive state to the reverse blocking state is referred to as the reverse recovery.

When the diode 530 bias signal 700 is changed from forward to reverse (i.e., the voltage applied to the diode's anode is changed from positive to negative) with a ramp rate discussed below, the current through the diode 530 does not monotonically reduces from a static forward level If to a static reverse level Ir shown in FIG. 3. The bias voltage changes from positive to negative until the diode 530 is able to support the negative voltage, and, consequently, a reverse recovery current pulse 600 occurs due to the stored charge carriers followed by the reduction of the current to zero or to Ir that absolute value is much smaller than If. Any diode has static characteristics such as forward current If, reverse current Ir (FIG. 3), and also dynamic characteristics such as reverse recovery current pulse 600 (FIG. 6). Native dynamic characteristics of diodes such as a reverse recovery current or forward voltage overshoot are usually considered as their disadvantage for standard usage diodes as rectifiers. Usually engineers attempt to minimize a reverse recovery current in so-called soft recovery diodes.

A diode 530 with the short charge carriers' lifetime provides high current to the storage element 510 then a signal 700 is applied between electrodes 520A and 520B of the memory device 500 due to the reverse recovery current pulse 600.

Some embodiments of this invention use a reverse recovery current 600 for programming a crossbar memory device 500 into one of plurality of states that includes one or more reset states there a subsystem of a storage element 510 is mostly disordered, and one or more set states there the subsystem of the storage element 510 is at least partially ordered. The subsystem is the atomic system for PCA or/and the electron system or/and the dipole system or/and the magnetic system or/and the subsystem of excitations for various different storage elements 510. In order to create a reverse recovery current pulse 600 flows through a crossbar memory device 500 a signal (e.g., a voltage) applied to the device 700 changes from positive polarity that correspond forward bias of a diode 530 to negative polarity that correspond reverse bias of the diode 530.

The reverse recovery current pulse 600 shown in FIG. 6 has a leading edge 606 during which current changes from If to a peak value 608, and a trailing edge 610 during which the reverse recovery current changes from the peak value 608 to Ir or essentially zero. The duration of the reverse recovery current pulse 600 is from 10 ns to 10 us. The speed of the reverse recovery current pulse reduction from the peak 608 to Ir or zero value (i.e. the trailing edges 610A or 610B or 610C) is used to program a memory device 500 into different states. A storage element 510 of a crossbar memory device 500 shown in FIG. 5 can be programmed by electrical pulses regardless of polarity of these pulses. The peak amplitude 608A (or 608B) heats up a region within the storage element 510 based on PCA above the melting temperature Tm in one embodiment. The peak amplitude 608C heats up a region within the storage element 510 based on PCA above the crystallization temperature Tx or glass transition temperature Tg in some embodiments.

The reverse recovery current pulse 600 with the trailing edge 610C programs the memory device 500 into a set state if the duration of the trailing edge exceeds 50 ns. Preferably the duration of the trailing edge 610C is between 100 ns and 500 ns in some embodiments. The reverse recovery current pulses 600 with the trailing edge 610A and 610B program the memory device 500 into two different reset states if their duration is below 50 ns. Preferably the duration of the pulse's trailing edge 610A or 610B is between 1 ns and 10 ns in some embodiments.

A current density at the peak 608 of the reverse recovery current 600 exceeds in 3-20 times the current density of a forward current If through a diode 530. The peak value and a duration of the reverse recovery current pulse depend on the forward current value, or/and a rate of the signal (voltage) polarity change, and/or construction of a diode 530, and of a storage element 510, and of a whole memory device 500.

The forward current If that correspond to positive bias signal polarity is not big enough to change a storage element 510 state, e.g., If is below 200 uA, preferably below 2 uA. Contrary the reverse recovery current peak 608 is big enough to change a storage element 510 state, e.g., it is above 100 uA, preferably it is above 1 mA. A reverse recovery current pulse 610 with fast reduction of from peak value to Jr or to zero during the trailing edge 610A (or 610B) is used to program a memory device 500 into one or more of the reset states. A reverse recovery current pulse 600 with slow reduction from the peak 608C to Ir during the trailing edge 610C is used to program a memory device 500 into one or more of the set states.

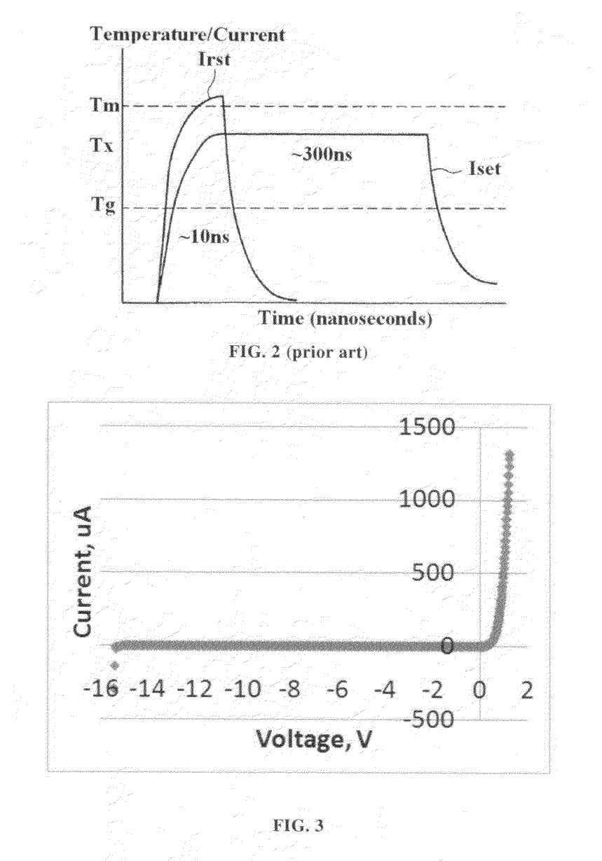

In some embodiments the forward current If is used for programming of a memory device 500 into one or more of the set states while the reverse recovery current pulse 600 is used for programming of a memory device 500 into one or more of the reset states. A programming pulse for a set state according to these embodiments is shown in FIG. 2. In some other embodiments the reverse recovery current pulses 600 are used to program a memory device in any of set and reset states. Programming pulses for these embodiments are shown in FIG. 7.

Exemplary signals 700A and 700B for programming a memory device 500 into one or more of the reset states are shown in FIG. 7. Exemplary signal 700A for programming a memory device 500 into one or more of the set states is also shown in FIG. 7. The indexes r and ′r (prime-r) indicate signals for programming a memory device 500 into a reset state, and the index s indicates signals for programming a memory device 500 into a set state in FIG. 7.

The applied signal 700 starts at a time t0. An amplitude of the signal 700 is equal to a value A1 during period between time moments t0 and t1. During this period t1-t0 the signal 700 polarity corresponds to a forward bias of a diode 530. During this period t1-t0 a static forward current flows through the diode 530 and a whole memory device 500.

The applied signal 700 decreases from the value A1 to zero at the period between time moments t1 and t2 and to a value A2 at the moment t3 with ramp rate about (A1-A2)/(t3-t1). During the period t3-t2 the signal 700 polarity corresponds to a reverse bias of a diode 530. Due to a diode 530 properties, the change of the signal 700 during the period from t1 until t3 leads to a reverse recovery current pulse 600, in particular to the reverse recovery current pulse leading edge 606. Due to a diode 530 properties, the amplitude A1 and the ramp rate define the peak amplitude 608 of the reverse recovery current pulse 600. Change of a signal (e.g., the bias voltage) 700 on a crossbar memory device 500 occurs during less than 10 us, preferably during less than 10 ns. In this case an absolute value of reverse recovery current peak 608 is higher than static diode's forward current If.

The signal 700 amplitude returns to zero at the moment t4. During the period t4-t3 the signal 700 polarity corresponds to a reverse bias of a diode 530. Due to a diode 530 properties a reverse bias of the applied signal 700 in particular it amplitude A2 and the time interval t4-t3 define a duration of the trailing edge 610 of the reverse recovery current pulse 600.

The amplitude A1s of the signal 700C for programming a memory device 500 into a set state is smaller (or equal) than the amplitude A1r (or A′1r) of the signal 700A (or 700B) for programming a memory device 500 into a reset state. The period between time moments t1 and t3s of the signal 700C for programming a memory device 500 into a set state is smaller (or equal) than the period between time moments t 1r and t3r (or t′1r and t′3r) of the signal 700A (or 700B) for programming a memory device 500 into a reset state. The ramp rate (A1s-A2s)/(t3s-t1s) of the signal 700C for programming a memory device 500 into a set state is smaller than any of ramp rates of the signal 700A or the signal 700B for programming a memory device 500 into a reset state. The period from t3s until t4s of the set signal 700C is longer that the period from t3r until t4r of any reset signal 700A or 700B.

Anybody skilled in the art can easily recognize that the pulse 600 characteristics depend on a memory device 500 reactance and/or depend on diode 530 parameters, and/or depend on the applied signal 700. Anybody skilled in the art can easily build and program a crossbar memory device according to the above described embodiments of this invention.

A cross-point memory array compromises a plurality of crossbar memory devices 500 between bitlines and wordlines according some embodiments of this invention. The cross-point memory array has an active load with finite inductance or/and capacitance in some embodiments.

The load can have inductive or/and capacitive component related to the electrodes 520 or to the storage element 510, or to the array's bitline(s) or/and wordline(s), or to the array's active load.

A write circuit is connected with a cross-point memory array (FIG. 8) in order to provide necessary for programming of a crossbar memory device 500 forward current and ramp rate for signal change that lead to desired reverse recovery current. The memory array and the write circuit are coupled with an interface device, e.g. with a computer or a music player in some embodiments (FIG. 8).

Anybody skilled in the art can easily choose or design the write circuit, the interface device, the crossbar memory device, and the cross-point memory array described in embodiments of this invention.

The foregoing description of an example of the preferred embodiment of the invention and the variations thereon have been presented for the purposes of illustration and description. It is not intended to be exhaustive or to limit the invention to the precise forms disclosed. Many modifications and variations are possible in light of the above teaching. It is intended that the scope of the invention be limited not by this detailed description.

I claim:

1. A method of operating a crossbar memory device programmable to a plurality of states by a pulse created by a diode's reverse recovery current.

2. The method of claim 1, wherein said reverse recovery current has higher current density that a forward current of the diode.

3. The method of claim 1, wherein a change of an external signal applied to said crossbar memory device causes said reverse recovery current.

4. The method of claim 3, wherein said signal change occurs during less than 1 microsecond.

5. The method of claim 3, wherein said signal change occurs during less than 10 nanoseconds.

6. The method of claim 3, wherein said signal before said change corresponds to a positive diode polarity and forward diode current, and said signal after said change corresponds to a negative diode polarity and reverse diode current.

7. The method of claim 3, wherein said signal is a bias voltage applied to a memory device.

8. The method of claim 1, wherein said memory device selected from the group consisting of a phase-change memory (PCM, PRAM, PCRAM, PC-RAM), a resistive memory (RRAM), a magnitoresistive memory (MRAM), a polymer memory (PRAM), a molecular memory, a ferroelectric memory (FeRAM), an ionic memory (PMC), a memristive memory, a spin memory, an oxide memory such as ReRAM, 0xRAM, RRAM, a conductive bridging random access memory (CBRAM).

9. The method of claim 1, wherein said plurality of states includes one or more reset states there a subsystem of said phase change alloy is mostly disordered, and one or more set states there the subsystem of said phase change alloy is at least partially ordered; and in some embodiments said subsystem is the atomic system or/and the electron system or/and the dipole system or/and the magnetic system or/and the subsystem of excitations.

10. The method of claim 6, wherein said forward diode current is not enough to change a memory device state from a first state to a second state.

11. The method of claim 6, wherein said reverse diode current is not enough to change a memory device state from a first state to a second state.

12. The method of claim 6, wherein said forward diode current is below 1 mA.

13. The method of claim 6, wherein said forward diode current is below 2 uA.

14. The method of claim 6, wherein said reverse diode current is below 5 uA.

15. The method of claim 6, wherein said reverse diode current is below 0.01 pA.

16. The method of claim 9, wherein one or more said set states, have one or more properties with values below a predetermined value for this property; and one or more said reset states, have one or more properties with values above the predetermined value for this property, there the property can be selected from the group consisting of electrical resistance, electrical impedance, threshold switching voltage, electrical capacitance, electrical inductance, optical reflection, electron spin resonance signal.

17. The method of claim 1, wherein said memory device is programmed into one or more said reset states by said reverse recovery current.

18. The method of claim 1, wherein said memory device is programmed into one or more said set states by said reverse recovery current.

19. The method of claim 1, wherein said memory device is programmed into one or more said reset states by said reverse recovery current, and said memory device is programmed into one or more said set states by said forward diode current.

20. The method of claim 19, wherein said forward diode current used for said memory programming has finite duration.

21. The method of claim 19, wherein said forward diode current duration is smaller than 10 us, preferably smaller than 100 ns.

22. The method of claim 1, wherein said diode has a short charge carriers' lifetime.

23. The method of claim 22, wherein said lifetime is smaller than 3 us, preferably smaller than 100 ns.

24. A crossbar memory device comprising: a diode with a short charge carriers lifetime, and a storage element electrically coupled with the said diode; and at least one of them has finite (non-zero) reactance.

25. The crossbar memory device of claim 24, wherein a first electrically conductive electrode electrically and mechanically coupled with said storage element; and a second electrically conductive electrode electrically and mechanically coupled with said diode.

26. The crossbar memory device of claim 24, wherein said storage element includes a material selected from the group of a phase change alloy, or an ion conductor, or a metal-oxide, or a ferroelectric, or a perovskite, or a marnetoresistor, or a colossal magnetoresistive film, or a transition metal oxide, or a Mott insulator.

27. The crossbar memory device of claim 24, wherein one or both of said electrodes are made from a material selected from the group of a metal, a conductive semiconductor, an ion conductor, a carbon, a superconductor.

28. The crossbar memory device of claim 24, wherein at least one of said electrodes has a finite reactance.

29. The crossbar memory device of claim 24, wherein said storage element has a finite reactance.

30. A memory array compromising a plurality of memory devices, conductive wordlines, and conductive bitlines each memory device further comprising a diode with a short charge carriers lifetime, a storage element electrically coupled with the said diode, and an active load electrically coupled with said storage element.

31. The crossbar memory device of claim 30 wherein said storage element comprises a diode.

32. The crossbar memory device of claim 30 or claim 31, wherein said active load has a finite inductance.

33. The crossbar memory device of claim 30 or claim 31, wherein said active load has a finite capacitance.

34. The memory array of claim 30 or claim 31, wherein at least one of said wordlines has an active load.

35. The memory array of claim 30 or claim 31, wherein at least one of said bitlines has an active load.

36. The memory array of claim 34 or claim 35, wherein said active load has a finite inductance.

37. The memory array of claim 34 or claim 35, wherein said active load has a finite capacitance.

38. The memory array of claim 37, wherein said active load has finite inductance.

40. The memory array of claim 36, wherein said active load has finite capacitance.

41. The memory device or/and array of claims 32 or/and 36, wherein said inductance is below 1 mH.

42. The memory device or/and array of claims 33 or/and 37, wherein said capacitance is below 1 mF.

43. A cross-point memory comprising a write circuit, said memory array, and said write circuit provides signals that cause reverse recovery current of a diode in said crossbar memory device.
